(19) United States
(12) Patent Application Publication
(10) Pub. No.: US 2013/0069064 A1
(43) Pub. Date: Mar. 21, 2013

(54) SEMICONDUCTOR DEVICE

(71) Applicant: Takayuki YOSHIHIRA, Yokohama-shi (JP)

(72) Inventor: Takayuki YOSHIHIRA, Yokohama-shi (JP)

(73) Assignee: Kabushiki Kaisha Toshiba, Tokyo (JP)

(21) Appl. No.: 13/424,323

(22) Filed: Mar. 19, 2012

(30) Foreign Application Priority Data
Sep. 20, 2011 (JP) 2011-204366

(51) Int. Cl. H01L 27/06

(52) U.S. Cl. 257/49; 257/E27.016

(57) ABSTRACT

A semiconductor device has a transistor in which a resistance is inserted between a gate electrode and a source electrode, and a diode inserted between the gate electrode and the source electrode in series in relation to the resistance.

### CROSS-REFERENCE TO RELATED APPLICATION

This application is based upon and claims the benefit of priority from the prior Japanese Patent Application No. 2011-204366, filed on Sep. 20, 2011; the entire contents of which are incorporated herein by reference.

### FIELD

Embodiments described herein relate generally to a MOSFET (Metal-Oxide-Semiconductor Field-Effect Transistor) in which a resistance for pull-down is connected to a gate electrode.

### BACKGROUND

Usually, in a drive circuit of a MOSFET, a resistance R_{GS} is often inserted between gate and source for the purpose of prevention of an abnormal oscillation of the MOSFET, discharge of a gate-source (G-S) capacitance, and pull-down of a gate electrode. However, in a case that a resistance R_{GS} is externally connected between gate and source of a MOSFET in a state of a bare chip, the purpose of pull-down is not achieved if a bonding wire of a gate is open, that is, is not connected to the outside.

On this occasion, if the MOSFET is turned on by a malfunction, there is an apprehension that an entire circuit including the MOSFET is destroyed. Thus, it is suggested that a semiconductor chip houses a resistance R_{GS} connecting between gate and source of a MOSFET or that a thin film resistor formed on a semiconductor chip connects between gate and source of a MOSFET.

### BRIEF DESCRIPTION OF THE DRAWINGS

FIG. 1A and a FIG. 1B are configuration diagrams of a semiconductor device according to an embodiment.

FIG. 2 is an equivalent circuit diagram of the semiconductor device according to the embodiment.

FIG. 3 is an equivalent circuit diagram of a semiconductor device according to a comparative example.

FIG. 4 is a characteristic chart of the semiconductor device according to the comparative example.

FIG. 5 and FIG. 6 are equivalent circuit diagrams of semiconductors according to other embodiments.

### DETAILED DESCRIPTION

A semiconductor device according to an embodiment has a transistor in which a resistance is inserted between a gate electrode and a source electrode, and a diode inserted between the gate electrode and the source electrode in series in relation to the resistance.

Hereinafter, the embodiments will be described in detail with reference to the drawings.

### Embodiment

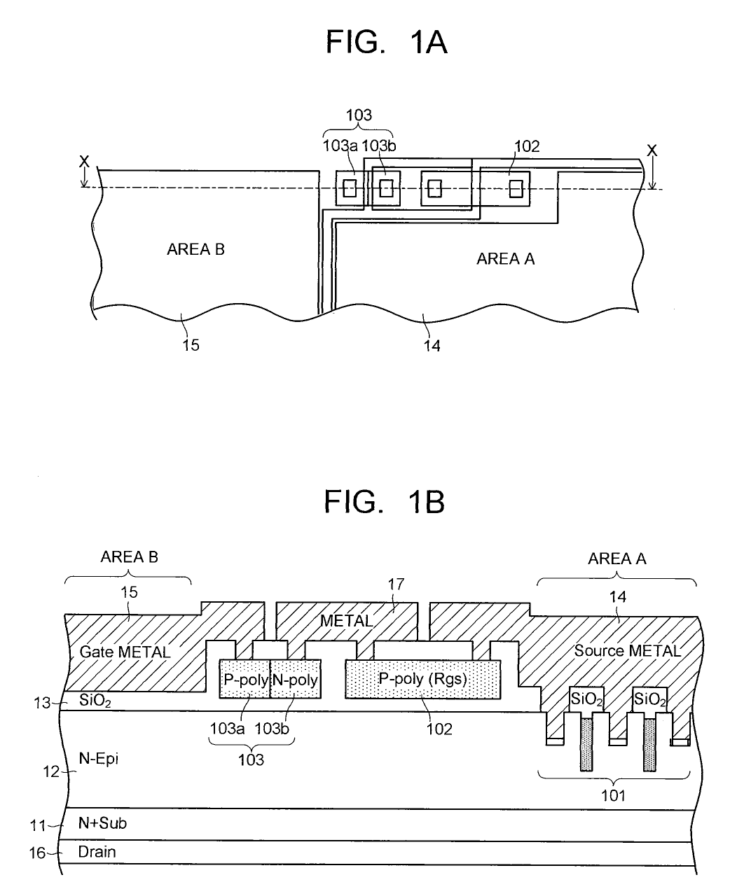

FIG. 1A and FIG. 1B are configuration diagrams of a semiconductor device 1 according to an embodiment. FIG. 1A is a top view of the semiconductor 1, while FIG. 1B is a cross-sectional view taken along a line X-X of FIG. 1A. Hereinafter, a configuration of the semiconductor 1 will be described with reference to FIG. 1A and FIG. 1B.

As depicted in FIG. 1A, most part of the semiconductor 1 according to the embodiment is a FET area A, and a gate electrode area B is formed in a corner. In the FET area A, a plurality of MOSFETs 101 are formed. A metal layer 14 to become a source electrode S is formed on an upper part of the plural MOSFETs 101. A metal layer 15 to become a gate electrode G is formed in the gate electrode area B.

As depicted in FIG. 1B, the semiconductor device 1 according to the embodiment has an n⁺ type silicon substrate 11, an n⁻ type epitaxial layer 12, a silicon oxide film 13, the plural MOSFETs 101, the metal layer 14 to become the source electrode S, the metal layer 15 to become the gate electrode G, a metal layer 16 to become a drain electrode D, a resistance 102, a diode 103, and a metal layer 17 connecting the resistance 102 and the diode 103.

The epitaxial layer 12 is formed on the silicon substrate 11. The silicon oxide film 13 is formed on the epitaxial layer 12. The plural MOSFETs 101 are formed on the epitaxial layer 12 in the FET area A. The metal layer 16 is formed on a rear surface of the silicon substrate 11.

The resistance 102 is formed of p-type polysilicon (Poly-Si). One end of the resistance 102 is connected to the metal layer 14 to become the source electrode S and the other end thereof is connected to the metal layer 17. The diode 103 is formed of a p-type polysilicon (Poly-Si) part 103a and an n-type polysilicon (Poly-Si) part 103b. The p-type polysilicon part 103a of the diode 103 is connected to the metal layer 15 to become the gate electrode G. The n-type polysilicon part 103b of the diode 103 is connected to the metal layer 17.

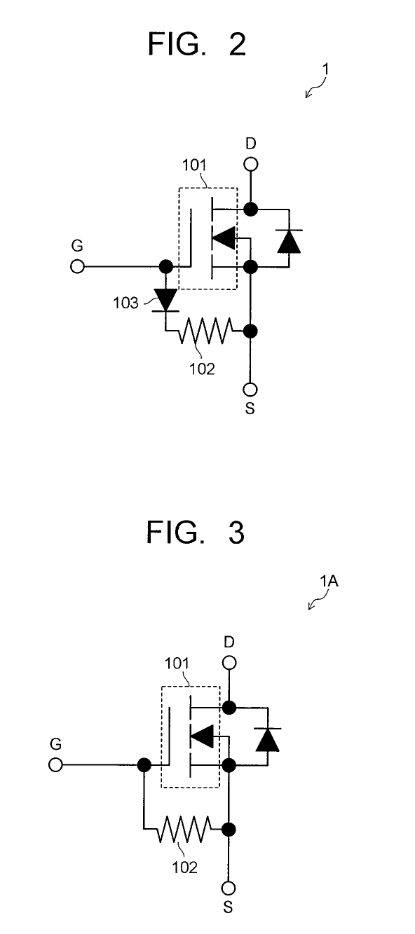

FIG. 2 is an equivalent circuit diagram of the semiconductor device 1 according to the embodiment. As depicted in FIG. 2, in the semiconductor device 1, there are formed the MOSFET 101 which has the gate electrode G, the drain electrode D, and the source electrode S and which is on/off controlled by application of a voltage to the gate electrode G, and the resistance 102 and the diode 103 inserted in series between the gate electrode G and the source electrode S (hereinafter, simply referred to as between gate and source) of the MOSFET 101. The resistance 102 is inserted between gate and source for the purpose of prevention of an abnormal oscillation of the MOSFET 101, discharge of a capacitance between gate and source, and pull-down of the gate electrode G. A resistance value of the resistance 102 is, for example, 100 kΩ.

The diode 103 is inserted between gate and source in series in relation to the resistance 102 in a manner that a direction from the gate electrode G to the source electrode S is a forward direction (a direction in which a current flows). As a result that the diode 103 is inserted between gate and source as above, a configuration is possible in which a current flows in the direction (hereinafter, referred to as the forward direction) from the gate electrode G to the source electrode S and a current does not flow in a direction (hereinafter, referred to as a reverse direction) from the source electrode S to the gate electrode G.

When measuring a leakage current IGSS after a gate shock test in which a voltage (for example, 5 MV/cm) is applied between gate and source, a voltage is applied in a manner that a current flows in a reverse bias, that it, in a direction from the source electrode S to the gate electrode G. Since a current does not flow in the reverse direction in the diode 103, a leakage current IGSS of a gate insulating film can be measured with a high accuracy (In practice, a small amount of leakage current occurs, but a value thereof is about 1 nA, a level which does not affect measurement of the IGSS).

On the other hand, since a current flows in the forward direction, by connecting the source electrode S to ground (GND), the resistance 102 inserted between gate and source functions for prevention of an abnormal oscillation of the MOSFET 101, discharge of a capacitance between gate and source, and pull-down of the gate electrode G. It should be noted that though in FIG. 2 the diode 103 is inserted between the gate electrode G and the resistance 102, the diode 103 can be inserted between the resistance 102 and the source electrode S.

### Comparative Example

FIG. 3 is an equivalent circuit diagram of a semiconductor device 1A according to a comparative example. The semiconductor device 1A depicted in FIG. 3 is different from the semiconductor device 1 described with reference to FIG. 2 in that a diode is not inserted between gate and source. Since other configurations are the same as those of the semiconductor device 1 described with reference to FIG. 2, the same configuration is given the same reference numeral and redundant explanation is omitted.

As depicted in FIG. 3, in the semiconductor device 1A according to the comparative example, a diode is not inserted between gate and source. Therefore, at a time of measurement of a leakage current IGSS after a gate shock test, a current I flows between a gate electrode G and a source electrode S via a resistance 102.

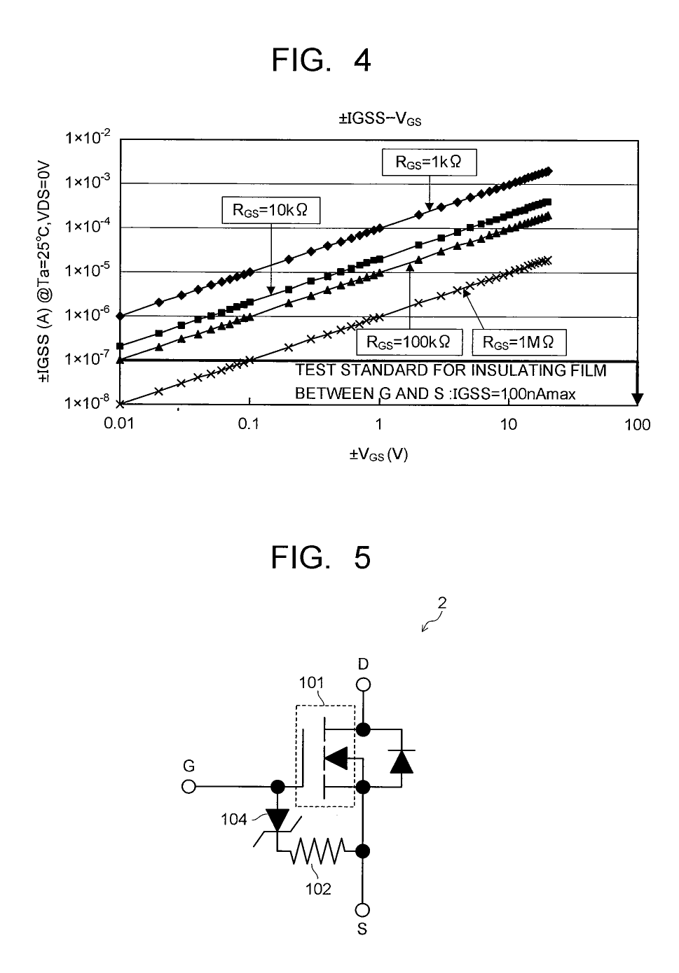

FIG. 4 is a chart indicating a relation between an applied voltage V_{GS} to between gate and source in a case that a resistance 102 is inserted between gate and source and a current I_{R} flowing in the resistance 102. In FIG. 4, a horizontal axis indicates the applied voltage V_{GS} to between gate and source while a vertical axis indicates a current value I_{R}. A result indicated in FIG. 4 is a result of measurement under a temperature of 25° C. and an applied voltage V_{DS} to between source and drain of 0V. A symbol R_{GS} in FIG. 4 indicates a resistance value (Ω) of the resistance 102.

As indicated in FIG. 4, in order to make the current value I_{R} flowing in the resistance 102 small, it is necessary to raise a resistance value of the resistance 102 or to lower a voltage V_{GS} applied to between gate and source. However, in a case of raising the resistance value of the resistance 102, if the resistance value of the resistance 102 is raised too much, a current becomes hard to flow in the resistance 102. Therefore, there is an apprehension that the resistance 102 does not function as pull-down of the gate.

Further, in a case of lowering the voltage V_{GS} applied to between gate and source, for example, even if the resistance value of the resistance 102 is 100 kΩ, in order to make the current value I_{R} flowing in the resistance 102 be 100 nA, which is the same as a threshold value of the leakage current IGSS, it is necessary to make the voltage V_{GS} applied to between gate and source be 10 mV.

Even in a case that the voltage V_{GS} applied to between gate and source is 10 mV, a leakage current IGSS of the gate insulating film occurs, but in order to keep the voltage V_{GS} applied to between gate and source at 10 mV, it is necessary to control a voltage with a high accuracy. Further, in order to measure the leakage current IGSS of the gate insulating film with a high accuracy, it is necessary to apply the voltage V_{GS} to between gate and source for a long period of time, which is not practical.

On the other hand, in the semiconductor device 1 according to the embodiment described in FIG. 2, the diode 103 is inserted between gate and source in series with the resistance 102. When measuring a leakage current IGSS after a gate shock test in which a voltage (for example, 5 MV/cm) is applied to between gate and source, a voltage is applied in a reverse bias, that is, in a direction from the source electrode S to the gate electrode G. Since in the diode 103 a current does not flow in the reverse direction, by applying the voltage in the reverse bias, the leakage current IGSS of the gate insulating film can be measured with a high accuracy.

On the other hand, since a current flows in the forward direction, by connecting the source electrode S to ground (GND), the resistance R_{GS} inserted between gate and source functions for prevention of an abnormal oscillation of the MOSFET 101, discharge of the capacitance between gate and source, and pull-down of the gate electrode G.

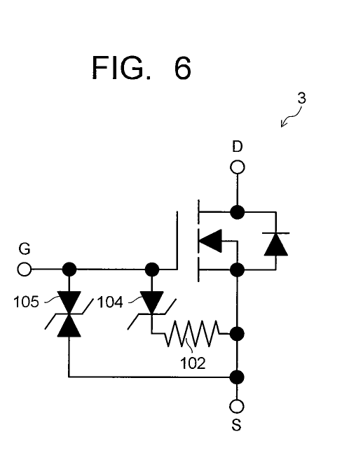

It should be noted that the diode 103 inserted between gate and source can be a Zener diode 104 as in a semiconductor device 2 depicted in FIG. 5. Further, a Zener diode 105 for ESD (electrostatic discharge) protection can be inserted between gate and source in parallel with a Zener diode 104 as in a semiconductor device 3 depicted in FIG. 6. In this case, since the Zener diode 105 for ESD protection is formed in parallel with the Zener diode 104 inside the semiconductor device 1, it is possible to form the Zener diode 105 for ESD protection in the same process step as that of the Zener diode 104. It should be noted that the Zener diode 105 for ESD protection can be external instead of being housed in the semiconductor device.

### Other Embodiments

While certain embodiments have been described, these embodiments have been presented by way of example only, and are not intended to limit the scope of the inventions. Indeed, the novel embodiments described herein may be embodied in a variety of other forms; furthermore, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a transistor in which a resistance is inserted between a gate electrode and a source electrode; and
a diode inserted between the gate electrode and the source electrode in series in relation to the resistance.

2. The device according to claim 1,
wherein the diode is inserted between the gate electrode and the source electrode in a manner that a direction from the gate electrode to the source electrode becomes a forward direction.

3. The device according to claim 1,
wherein the diode is a Zener diode.

4. The device according to claim 1,
wherein the source is connected to ground.

5. The device according to claim 1, further comprising a Zener diode inserted between the gate electrode and the source electrode in parallel with the resistance and the diode.

6. The device according to claim 1,
wherein the diode is formed inside the semiconductor device.

7. The device according to claim 1, wherein the device comprising a plurality of the transistors.

8. The device according to claim 1,
wherein the transistor is MOSFET.

9. The device according to claim 1,
wherein the diode is formed of a p-type polysilicon and an n-type polysilicon.

10. The device according to claim 9,
wherein the p-type polysilicon is connected to the gate electrode, and
then-type polysilicon is connected to the source electrode.
